(19) United States
(12) Patent Application Publication
(10) Pub. No.: US 2026/0107789 A1
(43) Pub. Date: Apr. 16, 2026

(54) SEMICONDUCTOR DEVICE INCLUDING A SEMICONDUCTOR TRANSISTOR DIE AND CLIPS FOR CONNECTING THE PADS OF THE SEMICONDUCTOR TRANSISTOR DIE

(71) Applicant: Infineon Technologies Austria AG, Villach (AT)

(72) Inventors: Kai Yiat Jim, Melaka Tengah (MY); Chin Hong Chio, Muar (MY); Zen Yin Lim, Klebang Besar (MY); Adbul Rahman Mohamed, Muar (MY); Joy Lie Velarde Guico, Laguna (PH)

(21) Appl. No.: 19/348,244

(22) Filed: Oct. 2, 2025

(30) Foreign Application Priority Data
Oct. 11, 2024 (DE) 102024129447.7

(51) Int. Cl. H01L 23/00; H01L 23/495; H01L 25/065

(52) U.S. Cl. CPC H10W 70/481; H10W 90/00; H10W 72/60; H10W 72/631; H10W 90/766

(57) ABSTRACT

A semiconductor device includes: a leadframe having a die pad, first leads and second leads, the second leads being connected with a leadpost; a first lateral transistor die having a first pad, second pad and third pad; a first clip, configured to connect the first pad to the die pad, which is connected with the first leads; and a second clip, configured to connect the second pad to the leadpost of the second leads), the leadpost being disconnected from the die pad. The second clip includes a first section contacting the second pad of the first lateral transistor die, a second section contacting the leadpost of the second leads, and a middle section between the first and the second sections. The middle section has partly a smaller width than the second section.

### TECHNICAL FIELD

The present disclosure is related to a semiconductor device.

### BACKGROUND

Power semiconductor transistors can be electrically connected together to form an electrical circuit which is usually housed in a common package. One particular example is a semiconductor transistor device in which two GaN transistor dies are connected in parallel. For connecting the contact pads of the GaN transistor dies normally electrical clips are used to avoid the high costs of copper wire bonds. Problems like unwanted die tilt can arise due to the weight of the drain and source clips.

For these and other reasons there is a need for the present disclosure.

### SUMMARY

An aspect of the present disclosure is related to a semiconductor device, comprising a leadframe comprising a die pad, first leads and second leads, wherein the second leads are connected with a leadpost, a first lateral transistor die comprising a first pad, a second pad and a third pad, a first clip, configured to connect the first pad to the die pad, which is connected with the first leads, a second clip, configured to connect the second pad to the leadpost of the second leads, wherein the leadpost is disconnected from the die pad, wherein the second clip comprises a first section contacting the second pad of the first lateral transistor die, a second section contacting the leadpost of the second leads, and a middle section between the first and the second sections, wherein the middle section has partly a smaller width than the second section.

The feature that the middle section of the second clip has a smaller width than the second section, can be provided by different shapes of the second clip. In one of these the second clip comprises a shape of the letter “I”. In another one of these the second clip comprises a shape of the letter “Z”. In another one of these the second clip comprises a shape of the number “8”.

The second clip is usually the drain clip as will be shown in the examples later below. An important advantage of this form of the drain clip is that the weight of the drain clip can be significantly reduced compared to a form in which the drain clip only consists of a rectangle with also the middle section having the same width as the upper and lower sections.

The principal idea of some embodiments is that by reducing the size or width of the middle section of the second clip, not equally reducing the first section, middle section and the second section simultaneously, the whole weight of the second clip can be reduced without negatively impacting the bonding between the second clip and the second pad and the bonding between the second clip and the second lead.

As a result of this lower weight of the drain clip, the contact pressure of the drain clip on the semiconductor die can be reduced and the die tilt can be avoided or reduced.

In a conventional package, the drain clip, e.g., the second clip, is much heavier than a source clip, e.g., the first clip, so that the drain clip will exert a bigger gravity force than that of the source clip, which may further cause the die tilt, sometimes named as uneven BLT (bond line thickness). By using the improved clips in some of the embodiments of the present invention, the difference between the gravity force of the second clip exerting on the die and that force of the first clip will be greatly mitigated.)

Specific examples will be shown and described further below.

According to an embodiment of the semiconductor device, the first pad is a first source pad, the second pad is a first drain pad, and an optional further pad of the first semiconductor die is a first gate pad.

According to embodiment of the semiconductor device, the semiconductor device further comprises a second semiconductor transistor die comprising a fourth pad, a fifth pad, and a sixth pad. According to an example thereof, the fourth pad is a second source pad, the fifth pad is a second drain pad, and the sixth pad is a second gate pad.

According to embodiment of the semiconductor device, each one of the first semiconductor transistor die and the second semiconductor transistor die comprises a lateral transistor comprising a load current path in a direction parallel to one of the main surfaces of the semiconductor transistor die. According to an example thereof each one of the first semiconductor transistor die and the second semiconductor transistor die comprises a high electron mobility transistor (HEMT).

Furthermore one or both of the first semiconductor transistor die and the second semiconductor transistor die can be a wide band gap semiconductor transistor die, in particular a GaN or a SiC transistor die.

Furthermore the first semiconductor transistor die and the second semiconductor transistor die are configured as power semiconductor transistor dies. A power transistor is a switching device that is rated to accommodate voltages of at least 20 V (volts) and more commonly on the order of 100V, 600 V, 1200V or more and/or is rated to accommodate currents of at least 1 A (amperes) and more commonly on the order of 10 A, 50 A, 100 A or even more.

According to embodiment of the semiconductor device, the leadpost of the second leads is arranged at a higher plane than the die pad.

According to an embodiment of the semiconductor device, the first clip comprises a rectangular shape.

According to an embodiment of the semiconductor device, the first semiconductor die and the second semiconductor die are electrically connected in parallel with each other.

According to an embodiment of the semiconductor device, the semiconductor device in case of a second semiconductor transistor die further comprises a fourth clip, configured to connect the fourth pad to the die pad, and a fifth clip, configured to connect the fifth pad to the leadpost of the second leads, wherein the fifth clip comprises a first section contacting the fifth pad of the second lateral transistor die, a second section contacting the leadpost of the second leads, and a middle section between the first and the second sections, wherein the middle section has a smaller width than the second section.

In case of the previous embodiment, the fourth clip may comprise a shape identical or different from the shape of the second clip. In particular, the fourth clip may comprises a shape of the letter “I”, a shape of the letter “Z”, or a shape of the letter “B” or of the number “8”.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIGS. 1A and 1B show a top view (FIG. 1A) and a cross-sectional side view (FIG. 1B) on a semiconductor device with two semiconductor transistor dies connected with two respective I-shaped drain clips.

FIGS. 2A and 2B show a top view (FIG. 2A) and a cross-sectional side view (FIG. 2B) on a semiconductor device with two semiconductor transistor dies connected with two respective Z-shaped drain clips.

FIGS. 3A and 3B show a top view (FIG. 3A) and a cross-sectional side view (FIG. 3B) on a semiconductor device with two semiconductor transistor dies connected with two respective 8-shaped drain clips.

FIGS. 4A and 4B show a top view (FIG. 4A) and a cross-sectional side view (FIG. 4B) on a semiconductor device with two semiconductor transistor dies both connected with one large I-shaped drain clip.

FIGS. 5A and 5B show a top view (FIG. 5A) and a cross-sectional side view (FIG. 5B) on a semiconductor device with two semiconductor transistor dies both connected with one large Omega-shaped drain clip.

### DETAILED DESCRIPTION

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

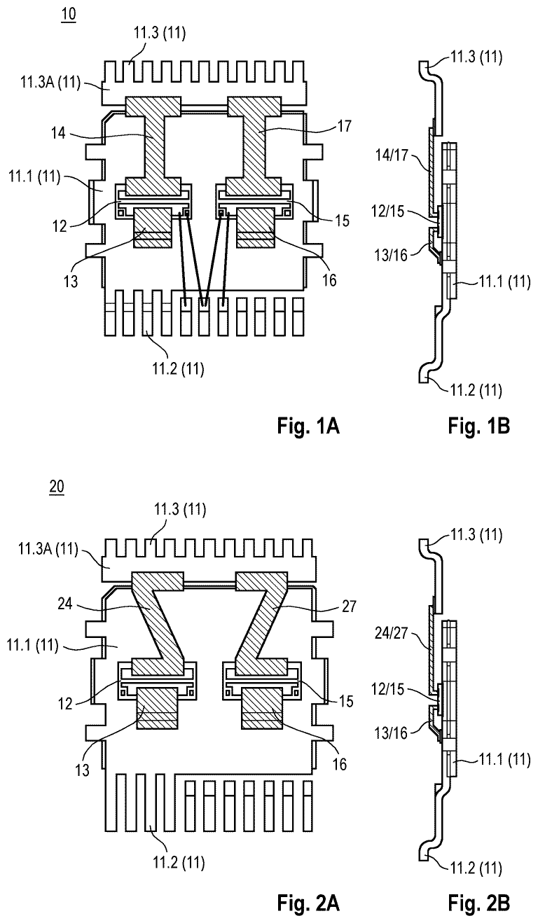

FIGS. 1A and 1B show a top view (FIG. 1A) and a cross-sectional side view (FIG. 1B) on a semiconductor device with two semiconductor transistor dies connected with two respective I-shaped drain clips.

The semiconductor device 10 as shown in FIG. 1A comprises a leadframe 11 comprising a die pad 11.1, first leads 11.2 and second leads 11.3, wherein the second leads 11.3 are connected with a leadpost 11.3A. A first lateral transistor die 12 is applied to the die pad 11.1a and comprises on a lower side a source pad, on an opposing upper side a drain pad and a further gate pad. The gate pad is located here on a corner position besides the source pad. However, it could also be located anywhere else and it is of no concern of the present disclosure. A second lateral transistor die 15 is also applied to the die pad 11.1a and comprises on a lower side a source pad, on an opposing upper side a drain pad on an edge of the lower side a gate pad.

The semiconductor device 10 furthermore comprises a first clip 13, configured to connect the source pad to the die pad 11.1, wherein the die pad 11.1 is connected with the first leads 11.2, in another word, the die pad 11.1 and the first leads 11.2 are physically integrated.

The semiconductor device 10 furthermore comprises a second clip 14 configured to connect the second pad to the leadpost 11.3A of the second leads 11.3, wherein the leadpost 11.3A is physically disconnected from the die pad 11. The second clip 14 is the drain clip in the shown embodiment.

The second clip 14 as shown in FIGS. 1A and 1B comprises the shape of the letter “I” and is thus one example of a shape comprising a first section contacting the second pad of the first lateral transistor die 12, a second section contacting the leadpost 11.3A of the second leads 11.3, and a third middle section connected between the first and the second sections, wherein the middle section has a smaller width than both the first and second sections.

As shown, the first section of the drain clip 14 is a crossbar that is connected to the drain pad of the first semiconductor transistor die 12. The second section of the drain clip 14 is also a crossbar, which is connected above the die pad 11.1 to the lead post 11.3A of the second leads 11.3. The first and second sections can have the same width, as in the embodiment shown. However, the width can also be different. The middle section connects the first and second sections and has a smaller width. For example, it can be between a quarter and a half of the width of one of the first or second sections.

As shown in FIG. 1B, the leadpost 11.3A is located in a plane higher than the die pad 11.1 and the drain lead 14 is above the pad 11.1 without contacting it and is connected to the lead post 11.3A of the second lead 11.3, sometimes the leadframe is named as a downset leadframe.

As already mentioned, in another embodiment, above the semiconductor device 10 furthermore comprises a second semiconductor transistor die 15 which is also applied to the die pad 11.1 and in the embodiment of FIGS. 1A and 1B formed identical with the first semiconductor die 12, i.e. comprising on a lower side a source pad, on an opposing upper side a drain pad, and on a corner of the lower side a gate pad.

The semiconductor device 10 furthermore comprises a third clip 16, configured to connect the source pad of the second semiconductor transistor die 15 to the die pad 11.1, and a fourth clip 17, configured to connect the drain pad of the second semiconductor transistor die 15 to the leadpost 11.3A of the second leads 11.3. The fourth clip 17 may have a similar shape as the second clip 14, namely a shape of the letter “I” comprising a first section contacting the fifth pad of the second lateral transistor die 15, a second section contacting the leadpost 11.3A of the second leads 11.3, and a middle section between the first and the second sections, wherein the middle section has a smaller width than the second section.

Each one of the first semiconductor transistor die 12 and the second semiconductor transistor die 15 may comprise a lateral transistor comprising a load current path in a direction parallel to one of the main surfaces of the semiconductor transistor die. Accordingly the source, drain and gate pads are disposed at the upper main face of the semiconductor dies. Furthermore each one of the first semiconductor transistor die 12 and the second semiconductor transistor die 15 may comprise a high electron mobility transistor (HEMT).

The configuration as shown in FIGS. 1A and 1B thus means that the first and second semiconductor transistor dies 12 and 15 are electrically connected in parallel to each other. Such configurations can be used in switching circuits of different as, for example, in DC/DC (buck), AC/DC, or DC/AC converter circuits.

FIGS. 2A and 2B show a top view (FIG. 2A) and a cross-sectional side view (FIG. 2B) on a semiconductor device with two semiconductor transistor dies connected with two respective Z-shaped drain clips.

The semiconductor device 20 as shown in FIG. 2A is similar to the semiconductor device 10 of FIGS. 1A and 1B, and is otherwise only different with respect to the shape of the drain clips.

The drain clips 24 and 27 as shown in FIGS. 2A and 2B each comprise the shape of the letter “Z” and is thus one other example of a shape comprising a first section contacting the second pad of the first lateral transistor die 12, a second section contacting the leadpost 11.3A of the second leads 11.3, and a third middle section connected between the first and the second sections, wherein the middle section has a smaller width than both the first and second sections.

As shown, the first section of the drain clips 24 and 27 is a crossbar that is connected to the respective drain pads of the two semiconductor transistor dies 12 and 15. The third section of the drain clips 24 and 27 is also a crossbar, which is connected above the die pad 11.1 to the lead post 11.3A of the second lead 11.3. The first and third sections can have the same width, as in the embodiment shown. However, the width can also be different. The second sections connect the first and third sections and have a smaller width. For example, it can be between a quarter and a half of the width of one of the first or third sections.

In contrast to the semiconductor device 10 of FIGS. 1A and 1B, the configuration as shown here in FIGS. 2A and 2B is such that the second middle section of the drain clip 24 does not form a vertical connection between the first and second sections of the drain clip. Rather, the corners of the first and second sections of the drain clip 24 are connected to each other by the second middle section of the drain clip 24, so that the inverted letter ‘Z’ is formed on the side of the first semiconductor transistor 12 as a result. On the opposite side of the second semiconductor transistor 15, this configuration results in a letter ‘Z’ being formed by the drain clip 27.

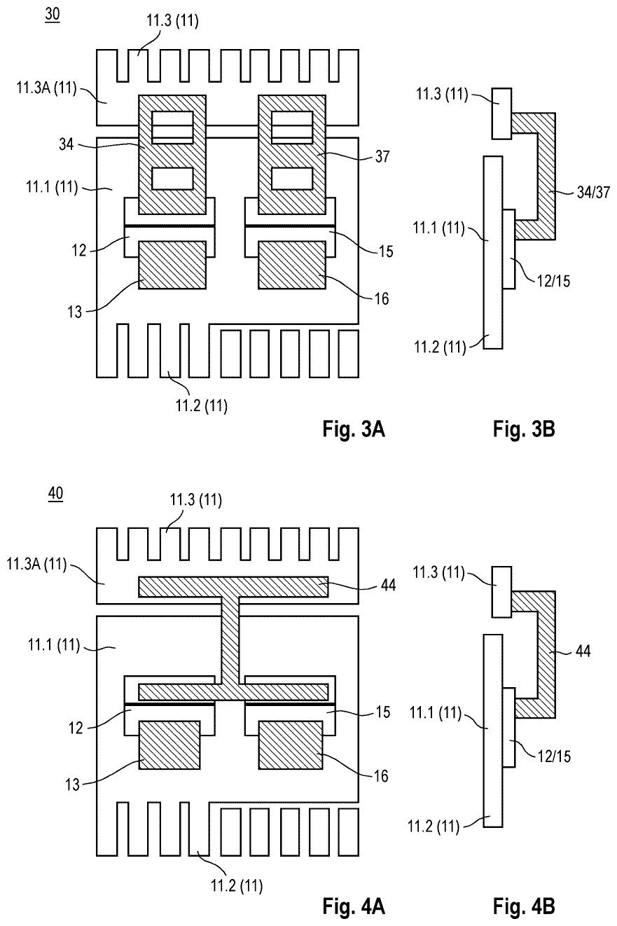

FIGS. 3A and 3B show a top view (FIG. 3A) and a cross-sectional side view (FIG. 3B) on a semiconductor device with two semiconductor transistor dies connected with two respective 8- or B-shaped drain clips.

The drain clips 34 and 37 as shown in FIGS. 3A and 3B each comprise the shape of the number “8” or the letter “B” and is thus one other example of a shape comprising a first section contacting the second pad of the first lateral transistor die 12, a second section contacting the leadpost 11.3A of the second leads 11.3, and a third middle section connected between the first and the second sections, wherein the middle section comprises only in part a smaller width than both the first and second sections.

A difference between this and the other previous embodiments is that is that the third middle section is not homogenous but is hollow so that the total weight of the drain clip decrease, therefore the total weight of the drain clip decreases and therefore the gravity force on the die pad is correspondingly reduced.

FIGS. 4A and 4B show a top view (FIG. 4A) and a cross-sectional side view (FIG. 4B) on a semiconductor device with two semiconductor transistor dies both connected with one large I-shaped drain clip.

Previous embodiments in FIGS. 1A to 3B have shown configurations of semiconductor devices comprising two drain clips connecting the respective two semiconductor transistor dies with the leadpost of the second leads. The embodiment as shown in FIGS. 4A and 4B now shows how one single drain clip 44 shaped in an “I” form connects the two semiconductor transistor dies 12 and 15 with the leadpost 11.3A.

In the embodiment of FIGS. 4A and 4B, one single drain clip 44 connects the drain pads of the two semiconductor transistor dies 12 and 15 with the leadpost 11.3A of the second leads 11.3. The drain clip 44 as shown in FIGS. 4A and 4B comprises the shape of the letter “I” and is again one example of a shape comprising a first section contacting the drain pads of the semiconductor transistor dies 12 and 15, a second section contacting the leadpost 11.3A of the second leads 11.3, and a third middle section connected between the first and the second sections, wherein the middle section has a smaller width than both the first and second sections.

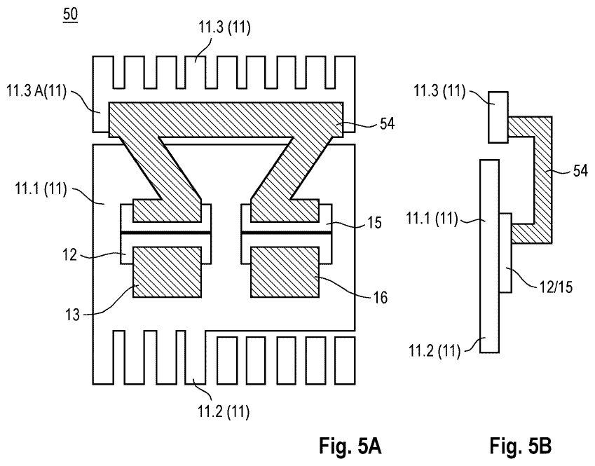

FIGS. 5A and 5B show a top view (FIG. 5A) and a cross-sectional side view (FIG. 5B) on a semiconductor device with two semiconductor transistor dies both connected with one large Omega-shaped drain clip.

Previous embodiments in FIGS. 1A to 3B have shown configurations of semiconductor devices comprising two drain clips connecting the respective two semiconductor transistor dies with the leadpost of the second leads. The embodiment as shown in FIGS. 5A and 5B now shows how one single drain clip 54 shaped in an “Omega” form connects the two semiconductor transistor dies 12 and 15 with the leadpost 11.3A.

In the embodiment of FIGS. 5A and 5B, one single drain clip 54 connects the drain pads of the two semiconductor transistor dies 12 and 15 with the leadpost 11.3A of the second leads 11.3. The drain clip 54 as shown in FIGS. 5A and 5B comprises the shape of the letter “Omega” and is again one example of a shape comprising a first section contacting the drain pads of the semiconductor transistor dies 12 and 15, a second section contacting the leadpost 11.3A of the second leads 11.3, and a third middle section connected between the first and the second sections, wherein the middle section has a smaller width than both the first and second sections.

In the following specific examples of the present disclosure are described.
Example 1 is a semiconductor device comprising a leadframe comprising a die pad, first leads and second leads, wherein the second leads are connected with a leadpost, a first lateral transistor die comprising a first pad, a second pad and a third pad, a first clip, configured to connect the first pad to the die pad, which is connected with the first leads, a second clip, configured to connect the second pad to the leadpost of the second leads, wherein the leadpost is disconnected from the die pad, wherein the second clip comprises a first section contacting the second pad of the first lateral transistor die, a second section contacting the leadpost of the second leads, and a middle section between the first and the second sections, wherein the middle section has partly a smaller width than the second section.
Example 2 is the the semiconductor device according to Example 1, wherein the leadpost of the second leads is arranged at a higher plane than the die pad.
Example 3 is the the semiconductor device according to Example 1 or 2, wherein the first pad is a first source pad, the second pad is a first drain pad, and the third pad is a first gate pad.
Example 4 is the the semiconductor device according to any one of the preceding Examples, wherein the second clip comprises a shape of the letter “I”.
Example 5 is the semiconductor device according to any one of Examples 1 to 3, wherein the second clip comprises a shape of the letter “Z”.
Example 6 is the semiconductor device according to any one of Examples 1 to 3, wherein the second clip comprises the shape of the number “8” or the letter “B”.
Example 7 is the semiconductor device according to any one of the preceding Examples, wherein the first clip comprises a rectangular shape.
Example 8 is the semiconductor device according to any one of the preceding Examples, further comprising a second semiconductor transistor die comprising a fourth pad, a fifth pad, and a sixth pad.
Example 9 is the semiconductor device according to Example 8, wherein the fourth pad is a second source pad, the fifth pad is a second drain pad, and the sixth pad is a second gate pad.
Example 10 is the semiconductor device according to Example 8 or 9, wherein the first semiconductor die and the second semiconductor die are electrically connected in parallel with each other.
Example 11 is the semiconductor device according to any one of Examples 8 to 10, further comprising a third clip, configured to connect the fourth pad to the die pad, a fourth clip, configured to connect the fifth pad to the leadpost of the second leads, wherein the fourth clip comprises a first section contacting the fifth pad of the second lateral transistor die, a second section contacting the leadpost of the second leads, and a middle section between the first and the second sections, wherein the middle section has a smaller width than the second section.
Example 12 is the semiconductor device according to any one of Examples 7 to 10, wherein the fourth clip comprises a shape of the letter “I”.
Example 13 is the semiconductor device according to any one of Examples 7 to 10, wherein the fourth clip comprises a shape of the letter “Z”.
Example 14 is the semiconductor device according to any one of Examples 7 to 10, wherein the fourth clip comprises the shape of the number “8” or the letter “B”.
Example 15 is the semiconductor device according to any one of the preceding Examples, wherein the first semiconductor transistor die comprises a lateral transistor die comprising a load current path in a direction parallel to one of the main surfaces of the semiconductor transistor die.

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. A semiconductor device, comprising:
a leadframe comprising a die pad, a plurality of first leads and a plurality of second leads, wherein the second leads are connected with a leadpost;
a first lateral transistor die comprising a first pad, a second pad and a third pad;
a first clip, configured to connect the first pad to the die pad, which is connected with the first leads;
a second clip, configured to connect the second pad to the leadpost of the second leads,
wherein the leadpost is disconnected from the die pad,
wherein the second clip comprises a first section contacting the second pad of the first lateral transistor die, a second section contacting the leadpost of the second leads, and a middle section between the first and the second sections,
wherein the middle section has partly a smaller width than the second section,
wherein the first clip directly connects the first pad of the first lateral transistor die to the die pad.

2. The semiconductor device of claim 1, wherein the second clip directly connects the second pad of the first lateral transistor die to the leadpost, and wherein first and second pads are located on an upper surface and on opposing ends of the first lateral transistor die.

3. The semiconductor device of claim 1, wherein the leadpost of the second leads is arranged at a higher plane than the die pad.

4. The semiconductor device of claim 1, wherein the first pad is a first source pad, the second pad is a first drain pad, and the third pad is a first gate pad.

5. The semiconductor device of claim 1, wherein the second clip comprises a shape of the letter I.

6. The semiconductor device of claim 1, wherein the second clip comprises a shape of the letter Z.

7. The semiconductor device of claim 1, wherein the second clip comprises the shape of the number 8 or the letter B.

8. The semiconductor device of claim 1, wherein the first clip comprises a rectangular shape.

9. The semiconductor device of claim 1, further comprising:
a second lateral transistor die comprising a fourth pad, a fifth pad, and a sixth pad.

10. The semiconductor device of claim 9, wherein the fourth pad is a second source pad, the fifth pad is a second drain pad, and the sixth pad is a second gate pad.

11. The semiconductor device of claim 9, wherein the first lateral transistor die and the second lateral transistor die are electrically connected in parallel with each other.

12. The semiconductor device of claim 9, further comprising:
a third clip, configured to connect the fourth pad to the die pad; and
a fourth clip, configured to connect the fifth pad to the leadpost of the second leads,
wherein the fourth clip comprises a first section contacting the fifth pad of the second lateral transistor die, a second section contacting the leadpost of the second leads, and a middle section between the first and the second sections,
wherein the middle section has a smaller width than the second section.

13. The semiconductor device of claim 12, wherein the fourth clip comprises a shape of the letter I.

14. The semiconductor device of claim 12, wherein the fourth clip comprises a shape of the letter Z.

15. The semiconductor device of claim 12, wherein the fourth clip comprises the shape of the number 8 or the letter B.

16. The semiconductor device of claim 1, wherein the first lateral transistor die comprises a load current path in a direction parallel to a main surface of the first lateral transistor die.

17. The semiconductor device of claim 1, wherein the first clip has a bigger width than that of the second clip, and/or the first clip has a smaller length than that of the second clip.
